(19) United States
(12) Patent Application Publication
(10) Pub. No.: US 2024/0251628 A1
(43) Pub. Date: Jul. 25, 2024

(54) DISPLAY SUBSTRATE, DISPLAY DEVICE AND FABRICATION METHOD

(71) Applicants: Hefei Xinsheng Optoelectronics Technology Co., Ltd., Hefei, Anhui (CN); BOE Technology Group Co., Ltd., Beijing (CN)

(72) Inventors: Tongshang SU, Beijing (CN); Jun LIU, Beijing (CN); Yongchao HUANG, Beijing (CN); Jun CHENG, Beijing (CN); Liangchen YAN, Beijing (CN); Shengping DU, Beijing (CN)

(21) Appl. No.: 18/016,442

(22) PCT Filed: Feb. 28, 2022
(86) PCT No.: PCT/CN2022/078396

§ 371 Date: Jan. 16, 2023

(51) Int. Cl. H10K 59/38; G09G 3/32; H10K 59/12; H10K 59/80; H10K 102/00

(52) U.S. Cl. CPC H10K 59/38; G09G 3/32; H10K 59/1201; H10K 59/8051; H10K 59/8052; G09G 2300/0408; H10K 2102/3031

(57) ABSTRACT

A display substrate, a display device and a fabrication method are disclosed. The display substrate includes: a base substrate, having a first light-emitting region, a second light-emitting region and a transparent region, where an orthographic projection of the transparent region on the base substrate does not overlap an orthographic projection of the first light-emitting region on the base substrate and an orthographic projection of the second light-emitting region on the base substrate; and a light-emitting member, located on a side of the base substrate and including a bottom-emitting light-emitting unit located in the first light-emitting region and a top-emitting light-emitting unit located in the second light-emitting region.

### FIELD

The present disclosure relates to the technical field of semiconductors, and particularly to a display substrate, a display device and a fabrication method.

### BACKGROUND

A transparent display device has advantages of being light and thin, being portable, supporting a 3D display technology, being low in energy consumption and the like. Besides, people may see through a screen and “grab” something in the screen to have new human-computer interaction experience.

A transparent product in the related art is single-side display and includes a display region and a transparent region. The display region is configured to display information, and the transparent region is configured to transmit light. The transparent region may be widely applied to a shopping mall window display. An appearance of a product can be seen through a window, and meanwhile, related information of the product can be displayed on a window screen which provides commodity prices or functions of the related product. However, with widening of an application range of the transparent display product, the transparent display product in the related art cannot meet demands of people. For example, information such as advertisements on a metro window need to be seen by people inside and outside a metro, so a double-side display transparent product is needed at this time.

### SUMMARY

Embodiments of the present disclosure provide a display substrate, a display device and a fabrication method. The display substrate includes: a base substrate, having a first light-emitting region, a second light-emitting region and a transparent region, where an orthographic projection of the transparent region on the base substrate does not overlap an orthographic projection of the first light-emitting region on the base substrate and an orthographic projection of the second light-emitting region on the base substrate; and a light-emitting member, located on a side of the base substrate and including a bottom-emitting light-emitting unit located in the first light-emitting region and a top-emitting light-emitting unit located in the second light-emitting region.

In a possible implementation, the bottom-emitting light-emitting unit includes a plurality of auxiliary bottom light-emitting devices emitting white light; and the display substrate further includes: a first color film part located between the base substrate and the light-emitting member and in the first light-emitting region, and the first color film part includes a plurality of first color filters which are in one-to-one correspondence with the auxiliary bottom light-emitting devices.

In a possible implementation, each auxiliary bottom light-emitting device includes: a bottom-emitting transparent anode, a bottom-emitting light-emitting layer and a bottom-emitting reflective cathode which are located on a side of the first color film part away from the base substrate in sequence; and in a same bottom-emitting light-emitting unit, bottom-emitting transparent anodes of all auxiliary bottom light-emitting devices are mutually spaced, bottom-emitting light-emitting layers of all auxiliary bottom light-emitting devices are of an integrated structure, and bottom-emitting reflective cathodes of all auxiliary bottom light-emitting devices are of an integrated structure.

In a possible implementation, the display substrate further includes a first driving unit located between the first color film part and the light-emitting member; and the first driving unit includes: a plurality of first thin-film transistors which are electrically connected with the auxiliary bottom light-emitting device in one-to-one correspondence.

In a possible implementation, an orthographic projection of the first driving unit on the base substrate does not coincide with an orthographic projection of the bottom-emitting light-emitting unit on the base substrate.

In a possible implementation, the top-emitting light-emitting unit includes a plurality of auxiliary top-emitting devices emitting white light; and the display substrate further includes: a second color film part located on a side of the light-emitting member facing away from the base substrate and in the second light-emitting region, and the second color film part includes a plurality of second color filters.

In a possible implementation, each auxiliary top-emitting device includes a top-emitting reflective anode, a top-emitting light-emitting layer and a top-emitting transparent cathode which are located on a side of the base substrate facing the second color film part in sequence; and in a same top-emitting light-emitting unit, top-emitting reflective anodes of all auxiliary top-emitting devices are mutually spaced, top-emitting light-emitting layers of all auxiliary top-emitting devices are of an integrated structure, and top-emitting transparent cathodes of all auxiliary top-emitting devices are of an integrated structure.

In a possible implementation, the display substrate further includes a second driving unit located between the base substrate and the light-emitting member; and the second driving unit includes: a plurality of second thin-film transistors which are electrically connected with the auxiliary top-emitting devices in one-to-one correspondence.

In a possible implementation, an orthographic projection of the top-emitting light-emitting unit on the base substrate covers an orthographic projection of the second driving unit on the base substrate.

In a possible implementation, the bottom-emitting transparent anodes and the top-emitting transparent cathodes are on a same layer and made of a same material.

In a possible implementation, the bottom-emitting reflective cathodes and the top-emitting reflective anodes are on a same layer and made of a same material.

In a possible implementation, the orthographic projection of the transparent region on the base substrate is located between the orthographic projection of the first light-emitting region on the base substrate and the orthographic projection of the second light-emitting region on the base substrate.

In a possible implementation, an area of the orthographic projection of the transparent region on the base substrate is approximately equal to an area of an orthographic projection of the first light-emitting region on the base substrate.

An embodiment of the present disclosure further provides a display device, including the display panel provided by the embodiment of the present disclosure.

An embodiment of the present disclosure further provides a fabrication method of the display substrate provided by the embodiment of the present disclosure, including: providing a base substrate, where the base substrate has a first light-emitting region, a second light-emitting region and a transparent region; forming a plurality of bottom-emitting transparent anodes of a plurality of auxiliary bottom light-emitting devices in the first light-emitting region on a side of the base substrate through a one-time patterning process; forming a plurality of top-emitting reflective anodes of a plurality of auxiliary top-emitting devices in the second light-emitting region on a side of the base substrate through a one-time patterning process; forming a plurality of bottom-emitting light-emitting layers of the plurality of auxiliary bottom light-emitting devices and a plurality of top-emitting light-emitting layers of the plurality of auxiliary top-emitting devices on one sides of the bottom-emitting transparent anodes away from the base substrate through a one-time patterning process; forming a plurality of bottom-emitting reflective cathodes of the plurality of auxiliary bottom light-emitting devices in the first light-emitting region on one sides of the bottom-emitting light-emitting layers away from the bottom-emitting transparent anodes through a one-time patterning process; and forming a plurality of top-emitting transparent cathodes of the plurality of auxiliary top-emitting devices in the second light-emitting region on one sides of the top-emitting light-emitting layers away from the top-emitting reflective anodes through a one-time patterning process.

### BRIEF DESCRIPTION OF THE DRAWINGS

FIG. 1 is a first schematic sectional view of a display substrate provided by an embodiment of the present disclosure.

FIG. 2 is a first schematic top view of a display substrate provided by an embodiment of the present disclosure.

FIG. 3 is a schematic partial enlarged view of a first light-emitting region in FIG. 1.

FIG. 4 is a schematic partial enlarged view of a second light-emitting region in FIG. 1.

FIG. 5 is a first schematic flow chart of fabrication of a display substrate provided by an embodiment of the present disclosure.

FIG. 6 is a second schematic flow chart of fabrication of a display substrate provided by an embodiment of the present disclosure.

FIG. 7 is a third schematic flow chart of fabrication of a display substrate provided by an embodiment of the present disclosure.

FIG. 8A is a schematic diagram of a display substrate having first thin-film transistors and second thin-film transistors provided by an embodiment of the present disclosure.

FIG. 8B is a schematic diagram of a display substrate having a first color film part provided by an embodiment of the present disclosure.

FIG. 8C is a schematic diagram of a display substrate having bottom-emitting transparent anodes provided by an embodiment of the present disclosure.

FIG. 8D is a schematic diagram of a display substrate having top-emitting reflective anodes provided by an embodiment of the present disclosure.

FIG. 8E is a schematic diagram of a display substrate having a pixel defining layer provided by an embodiment of the present disclosure.

FIG. 8F is a schematic diagram of a display substrate having bottom-emitting light-emitting layers and top-emitting light-emitting layers provided by an embodiment of the present disclosure.

FIG. 8G is a schematic diagram of a display substrate having bottom-emitting reflective cathodes provided by an embodiment of the present disclosure.

FIG. 8H is a schematic diagram of a display substrate having top-emitting transparent cathodes provided by an embodiment of the present disclosure.

FIG. 8I is a schematic diagram of a display substrate having a thin-film encapsulation layer provided by an embodiment of the present disclosure.

FIG. 8J is a schematic diagram of a display substrate having a packing layer 56 provided by an embodiment of the present disclosure.

FIG. 8K is a schematic diagram of a display substrate having an encapsulation cover plate provided by an embodiment of the present disclosure.

### DETAILED DESCRIPTION OF EMBODIMENTS

In order to make objectives, technical solutions and advantages of embodiments of the present disclosure clearer, the technical solutions of embodiments of the present disclosure will be clearly and fully described below with reference to the accompanying drawings of embodiments of the present disclosure. Apparently, the described embodiments are only some, but not all of embodiments of the present disclosure. Based on the described embodiments of the present disclosure, all other embodiments obtained by those ordinarily skilled in the art without creative work belong to the protection scope of the present disclosure.

Unless otherwise defined, technical or scientific terms used in the present disclosure should be understood commonly by those ordinarily skilled in the art of the present disclosure. “First”, “second” and similar words used in the present disclosure do not denote any sequence, quantity or significance, but are only used for distinguishing different components. “Include” or “contain” or similar words mean that a component or an item preceding the word covers components or items and their equivalents listed after the word without excluding other components or items. “Connection”, “joint” and similar words may include electrical connection, direct or indirect, instead of being limited to physical or mechanical connection. “Above”, “below”, “left”, “right” and the like are merely used to represent a relative position relationship, and after an absolute position of a described object changes, the relative position relationship may also change correspondingly.

In order to keep the following description of embodiments of the present disclosure clear and concise, detailed description of known functions and known components are omitted in the present disclosure.

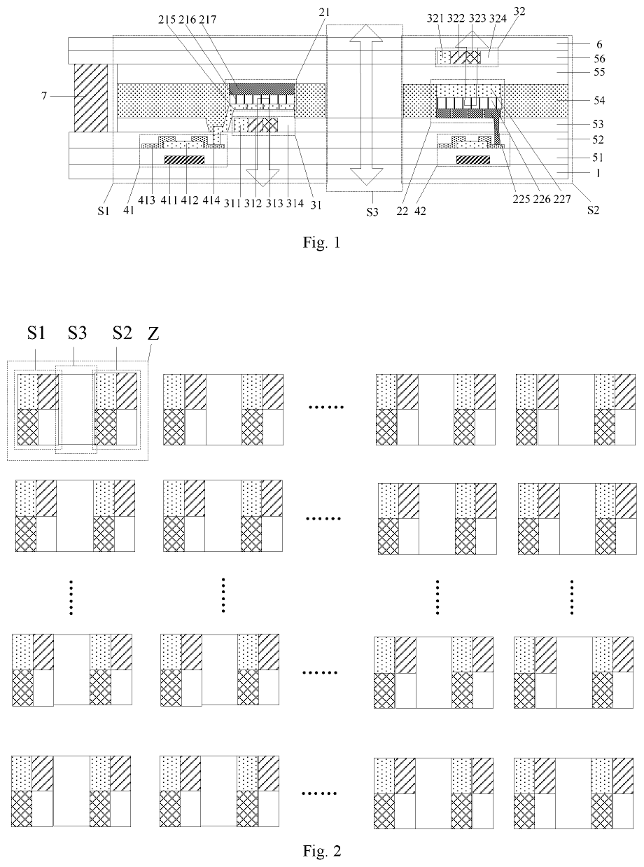

Referring to FIG. 1, an embodiment of the present disclosure provides a display substrate, including: a base substrate 1, having a first light-emitting region S1, a second light-emitting region S2 and a transparent region S3, where an orthographic projection of the transparent region S3 on the base substrate 1 does not overlap an orthographic projection of the first light-emitting region S1 on the base substrate 1 and an orthographic projection of the second light-emitting region S2 on the base substrate 1; and a light-emitting member, located on a side of the base substrate 1 and including a bottom-emitting light-emitting unit 21 located in the first light-emitting region S1 and a top-emitting light-emitting unit 22 located in the second light-emitting region S2. As shown by a thick arrow in FIG. 1, the bottom-emitting light-emitting unit 21 emits light towards a side facing the base substrate 1, and the top-emitting light-emitting unit 22 emits light towards a side away from the base substrate 1. The transparent region S3 may be located between the first light-emitting region S1 and the second light-emitting region S1. As shown in FIG. 2, the first light-emitting region S1, the second light-emitting region S2 and the transparent region S3 may be used as a repeating unit Z. The display substrate may include a plurality of repeating units Z. The plurality of repeating units Z are distributed in array on the display substrate.

In an embodiment of the present disclosure, the display substrate is provided with the bottom-emitting light-emitting unit 21 in the first light-emitting region S1 and the top-emitting light-emitting unit 22 in the second light-emitting region S2. Apart from the first light-emitting region S1 and the second light-emitting region S2, the display substrate is further provided with the transparent region S3, thus transparent display may be realized while double-side display may be realized, a display effect of a transparent product is improved, and an application range of the transparent product is widened.

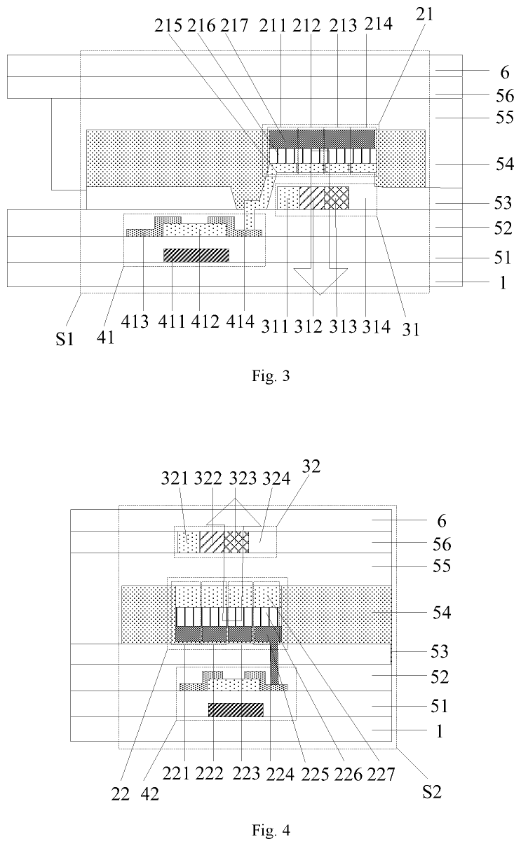

In a possible implementation, as shown in FIG. 1 and FIG. 3, FIG. 3 is a schematic enlarged view of a first light-emitting region S1 in FIG. 1. The bottom-emitting light-emitting unit 21 includes a plurality of auxiliary bottom light-emitting devices emitting white light. The display substrate further includes: a first color film part 31 located between the base substrate 1 and the light-emitting member and in the first light-emitting region S1. The first color film part 31 includes a plurality of first color filters which are in one-to-one correspondence with the auxiliary bottom light-emitting devices. For example, the plurality of auxiliary bottom light-emitting devices of the bottom-emitting light-emitting unit 21 may be: a first auxiliary bottom light-emitting device 211, a second auxiliary bottom light-emitting device 212, a third auxiliary bottom light-emitting device 213 and a fourth auxiliary bottom light-emitting device 214. The plurality of first color filters of the first color film part 31 may be: a first auxiliary color filter 311 corresponding to the first auxiliary bottom light-emitting device 211, a second auxiliary color filter 312 corresponding to the second auxiliary bottom light-emitting device 212, a third auxiliary color filter 313 corresponding to the third auxiliary bottom light-emitting device 213 and a fourth auxiliary color filter 314 corresponding to the fourth auxiliary bottom light-emitting device 214. The first auxiliary color filter 311 may be a red color filter, the second auxiliary color filter 312 may be a green color filter, the third auxiliary color filter 313 may be a blue color filter, the fourth auxiliary color filter 314 may be a transparent color filter, and thus the bottom-emitting light-emitting unit 21 may have four sub-pixels of red, green, blue and white.

In an embodiment of the present disclosure, the bottom-emitting light-emitting unit 21 includes the plurality of auxiliary bottom light-emitting devices emitting white light, the display substrate further includes: the first color film part 31 located between the base substrate 1 and the light-emitting member and in the first light-emitting region S1, the first color film part 31 includes the plurality of first color filters which are in one-to-one correspondence with the auxiliary bottom light-emitting devices, and the display substrate may realize color display by matching the auxiliary bottom light-emitting devices emitting white light with a color film.

During specific implementation, the display substrate may be not provided with the first color film part 31. In this case, the bottom-emitting light-emitting unit 21 may include an auxiliary bottom light-emitting device emitting red light directly, an auxiliary bottom light-emitting device emitting green light directly, an auxiliary bottom light-emitting device emitting blue light directly and an auxiliary bottom light-emitting device emitting white light directly.

In a possible implementation, as shown in FIG. 1 or FIG. 3, each auxiliary bottom light-emitting device includes a bottom-emitting transparent anode 215, a bottom-emitting light-emitting layer 216 and a bottom-emitting reflective cathode 217 which are located on a side of the first color film part 31 away from the base substrate 1 in sequence. In a same bottom-emitting light-emitting unit 21, bottom-emitting transparent anodes 215 of all auxiliary bottom light-emitting devices are mutually spaced, bottom-emitting light-emitting layers 216 of all auxiliary bottom light-emitting devices are of an integrated structure, and bottom-emitting reflective cathodes 217 of all auxiliary bottom light-emitting devices are of an integrated structure. Accordingly, a fabrication process of a double-side transparent display substrate can be simplified. The bottom-emitting transparent anodes 215 of all the auxiliary bottom light-emitting devices in the same bottom-emitting light-emitting unit 21 may be formed through a one-time patterning process.

In a possible implementation, as shown in FIG. 1 or FIG. 3, the display substrate further includes a first driving unit located between the first color film part 31 and the light-emitting member. The first driving unit includes: a plurality of first thin-film transistors 41 which are electrically connected with the auxiliary bottom light-emitting devices in one-to-one correspondence. Accordingly, all the auxiliary bottom light-emitting devices are driven to emit light. Each first thin-film transistor 41 may include a gate 411, an active layer 412, a source electrode 413 and a drain electrode 414 which are located on a side of the base substrate 1 in sequence.

It should be noted that in FIG. 1 or FIG. 3, in order to more clearly illustrate a structure of the first thin-film transistor 41, only one first thin-film transistor 41 is shown, but embodiments of the present disclosure are not limited to this. Each auxiliary bottom light-emitting device may be correspondingly electrically connected with one first thin-film transistor 41, and thus independent light-emitting control over each auxiliary bottom light-emitting device is realized.

In a possible implementation, an orthographic projection of the first driving unit on the base substrate 1 does not coincide with an orthographic projection of the bottom-emitting light-emitting unit 21 on the base substrate 1. Accordingly, the first thin-film transistor 41 can be prevented from blocking when the bottom-emitting light-emitting unit 21 emits light on a side facing the base substrate 1.

In a possible implementation, as shown in FIG. 1 and FIG. 4, FIG. 4 is a schematic enlarged view of a second light-emitting region S2 in FIG. 1. The top-emitting light-emitting unit 22 includes a plurality of auxiliary top-emitting devices emitting white light. The display substrate further includes a second color film part 32 located on a side of the light-emitting member facing away from the base substrate 1 and in the second light-emitting region S2, and the second color film part 32 includes a plurality of second color filters. For example, the plurality of auxiliary top-emitting devices of the top-emitting light-emitting unit 22 may be: a first auxiliary top-emitting device 221, a second auxiliary top-emitting device 222, a third auxiliary top-emitting device 223 and a fourth auxiliary top-emitting device 224. The plurality of second color filters of the second color film part 32 may be: a fifth auxiliary color filter 321 corresponding to the first auxiliary top-emitting device 221, a sixth auxiliary color filter 322 corresponding to the second auxiliary top-emitting device 222, a seventh auxiliary color filter 323 corresponding to the third auxiliary top-emitting device 223, and an eighth auxiliary color filter 324 corresponding to the fourth auxiliary top-emitting device 224. The fifth auxiliary color filter 321 may be a red color filter, the sixth auxiliary color filter 322 may be a green color filter, the seventh auxiliary color filter 323 may be a blue color filter, the eighth auxiliary color filter 324 may be a transparent color filter, and thus the top-emitting light-emitting unit 22 may have four sub-pixels of red, green, blue and white.

In an embodiment of the present disclosure, the top-emitting light-emitting unit 22 includes the plurality of auxiliary top-emitting devices emitting white light, the display substrate further includes: the second color film part 32 located on a side of the light-emitting member facing away from the base substrate 1 and in the second light-emitting region S2, the second color film part 32 includes the plurality of second color filters, and thus the display substrate may realize color display by matching the auxiliary top-emitting devices emitting white light with a color film.

During specific implementation, the display substrate may be not provided with the second color film part 32. In this case, the top-emitting light-emitting unit 22 may include an auxiliary top-emitting device emitting red light directly, an auxiliary top-emitting device emitting green light directly, an auxiliary top-emitting device emitting blue light directly and an auxiliary top-emitting device emitting white light directly.

In a possible implementation, as shown in FIG. 1 or FIG. 4, each auxiliary top-emitting device includes a top-emitting reflective anode 225, a top-emitting light-emitting layer 226 and a top-emitting transparent cathode 227 which are located on a side of the base substrate 1 facing the second color film part 32 in sequence. In a same top-emitting light-emitting unit 22, top-emitting reflective anodes 225 of all auxiliary top-emitting devices are mutually spaced, top-emitting light-emitting layers 226 of all auxiliary top-emitting devices are of an integrated structure, and top-emitting transparent cathodes 227 of all auxiliary top-emitting devices are of an integrated structure. Accordingly, a fabrication process of a double-side transparent display substrate can be simplified.

In a possible implementation, as shown in FIG. 1 or FIG. 4, the display substrate further includes a second driving unit located between the base substrate 1 and the light-emitting member 2, and the second driving unit includes: a plurality of second thin-film transistors 42 which are electrically connected with the auxiliary top-emitting devices in one-to-one correspondence. Accordingly, all the auxiliary top-emitting devices are driven to emit light. Similar to a structure of the first thin-film transistor 41, each second thin-film transistor 42 may include a gate, an active layer, a source electrode and a drain electrode which are located on a side of the base substrate 1 in sequence. The gate, the active layer, the source electrode and the drain electrode of the second thin-film transistor 42 may be arranged on the same layer as the gate, the active layer, the source electrode and the drain electrode of the first thin-film transistor correspondingly, that is, each film layer of the second thin-film transistor 42 is formed while each film layer of the first thin-film transistor 41 is formed.

It should be noted that in FIG. 1 or FIG. 4, in order to more clearly illustrate a structure of the second thin-film transistor 42, only one second thin-film transistor 42 is shown, but embodiments of the present disclosure are not limited to this. Each auxiliary top-emitting device may be correspondingly electrically connected with one second thin-film transistor 42, and thus independent light-emitting control over each auxiliary top-emitting device is realized.

In a possible implementation, as shown in FIG. 1 or FIG. 4, an orthographic projection of the top-emitting light-emitting unit 22 on the base substrate 1 covers an orthographic projection of the second driving unit on the base substrate. Accordingly, a light transmittance of the display substrate can be improved, so that the display substrate may have a larger transparent region.

In a possible implementation, as shown in FIG. 1, the bottom-emitting transparent anodes 215 and the top-emitting transparent cathodes 227 are on a same layer and made of a same material. Accordingly, the bottom-emitting transparent anodes 215 and the top-emitting transparent cathodes 227 may be formed through a one-step patterning process, and thus a fabrication process of the display substrate may be simplified. After the top-emitting reflective anodes 225 and the top-emitting light-emitting layers 226 of the auxiliary top-emitting devices are formed, the top-emitting transparent cathodes 227 and the bottom-emitting transparent anodes 215 may be formed through a one-step patterning process, and then the bottom-emitting light-emitting layers 216 and the bottom-emitting reflective cathodes 217 of the auxiliary bottom light-emitting devices are formed.

In a possible implementation, as shown in FIG. 1, the bottom-emitting reflective cathodes 217 and the top-emitting reflective anodes 225 are on a same layer and made of a same material. Accordingly, the bottom-emitting reflective cathodes 217 and the top-emitting reflective anodes 225 may be formed through a one-step patterning process, and thus a fabrication process of the display substrate may be simplified. After the bottom-emitting transparent anodes 215 and the bottom-emitting light-emitting layers 216 of the auxiliary bottom light-emitting devices are formed, the bottom-emitting reflective cathodes 217 and the top-emitting reflective anodes 225 are formed through a one-step patterning process, and then the top-emitting light-emitting layers 226 and the top-emitting transparent cathodes 227 of the auxiliary top-emitting devices are formed.

In a possible implementation, as shown in FIG. 1 and FIG. 2, an orthographic projection of the transparent region S3 on the base substrate 2 is located between an orthographic projection of the first light-emitting region S1 on the base substrate 1 and an orthographic projection of the second light-emitting region S2 on the base substrate 1.

In a possible implementation, as shown in FIG. 1 and FIG. 2, an area of the orthographic projection of the transparent region S3 on the base substrate 1 is approximately equal to an area of the orthographic projection of the first light-emitting region S1 on the base substrate 1. The orthographic projection of the first light-emitting region S1 on the base substrate 1 may also be approximately equal to an area of the orthographic projection of the second light-emitting region S2 on the base substrate 1. During specific implementation, due to process errors, the area of the orthographic projection of the transparent region S3 on the base substrate 1 is required to be completely equal to the area of the orthographic projection of the first light-emitting region S1 on the base substrate 1, which is highly difficult. In an embodiment of the present disclosure, the area of the orthographic projection of the transparent region S3 on the base substrate 1 is approximately equal to the area of the orthographic projection of the first light-emitting region S1 on the base substrate 1, and it can be understood as a ratio of a difference between the two to any of them is smaller than 10%.

In a possible implementation, as shown in FIG. 1 to FIG. 4, the substrate further includes an encapsulation cover plate 6 located on a side of the second color film part 32 away from the light-emitting member.

The display substrate may further include a gate insulation layer 51 located between the gate 411 and the active layer 412, a passivation layer 52 located between the source electrode 423 and the first color film part 31, a flat layer 53 located between the first color film part 31 and the light-emitting member, a pixel defining layer 54 located on a side of the top-emitting reflective anode 225 facing away from the flat layer 53, a thin-film encapsulation layer 55 located between the top-emitting transparent cathode 227 and the second color film part 32 and a packing layer 56 located between the second color film part 32 and the encapsulation cover plate 6.

In an embodiment of the present disclosure, materials of the base substrate 1, the gate insulation layer 51, the passivation layer 52, the flat layer 53, the thin-film encapsulation layer 55 and the packing layer 56 may be a transparent material. A frame region of the display substrate may also be provided with sealant 7.

Based on the same inventive concept, an embodiment of the present disclosure further provides a display panel, including the display substrate provided by embodiments of the present disclosure.

Based on the same inventive concept, an embodiment of the present disclosure further provides a display device, including the display panel provided by embodiments of the present disclosure.

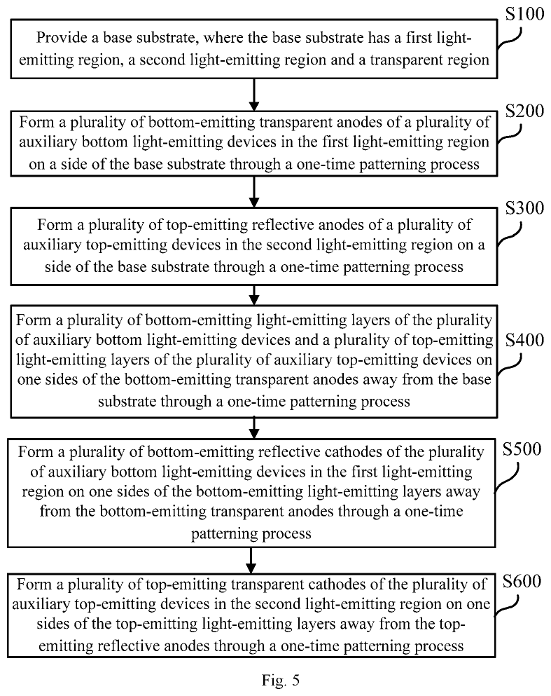

Based on the same inventive concept, an embodiment of the present disclosure further provides a fabrication method of the display substrate provided by embodiments of the present disclosure, as shown in FIG. 5, including following steps.

Step S100, a base substrate is provided, where the base substrate has a first light-emitting region, a second light-emitting region and a transparent region.

Step S200, a plurality of bottom-emitting transparent anodes of a plurality of auxiliary bottom light-emitting devices are formed in the first light-emitting region on a side of the base substrate through a one-time patterning process.

Step S300, a plurality of top-emitting reflective anodes of a plurality of auxiliary top-emitting devices are formed in the second light-emitting region on a side of the base substrate through a one-time patterning process.

Step S400, a plurality of bottom-emitting light-emitting layers of the plurality of auxiliary bottom light-emitting devices and a plurality of top-emitting light-emitting layers of the plurality of auxiliary top-emitting devices are formed on one sides of the bottom-emitting transparent anodes away from the base substrate through a one-time patterning process.

Step S500, a plurality of bottom-emitting reflective cathodes of the plurality of auxiliary bottom light-emitting devices are formed in the first light-emitting region on one sides of the bottom-emitting light-emitting layers away from the bottom-emitting transparent anodes through a one-time patterning process.

Step S600, a plurality of top-emitting transparent cathodes of the plurality of auxiliary top-emitting devices are formed in the second light-emitting region on one sides of the top-emitting light-emitting layers away from the top-emitting reflective anodes through a one-time patterning process.

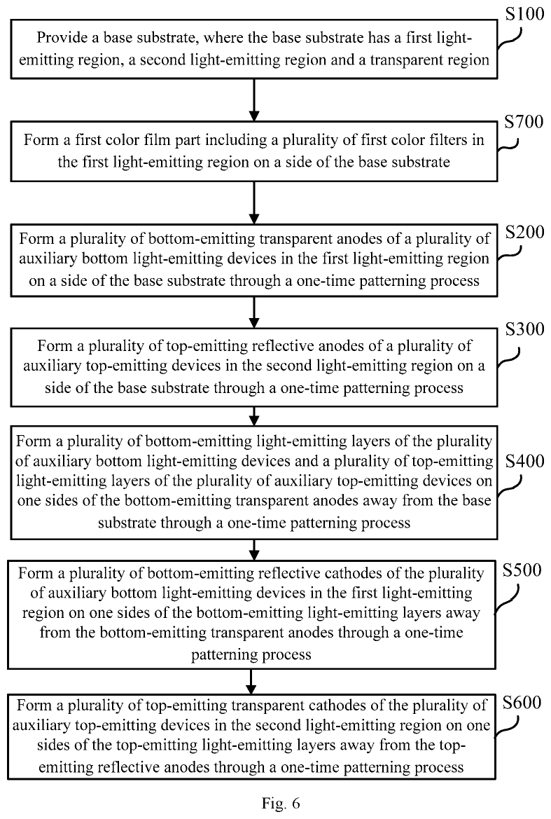

In a possible implementation, as shown in FIG. 6, before step S200, that is, before the plurality of bottom-emitting transparent anodes of the plurality of auxiliary bottom light-emitting devices are formed in the first light-emitting region on a side of the base substrate through the one-time patterning process, the fabrication method further includes the following step.

Step S700, a first color film part including a plurality of first color filters are formed in the first light-emitting region on a side of the base substrate.

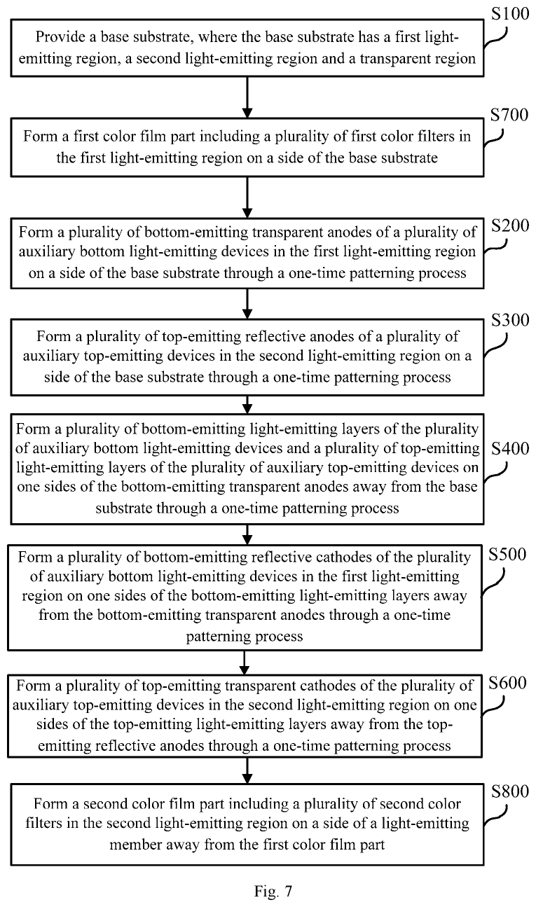

In a possible implementation, as shown in FIG. 7, after step S600, that is, after the plurality of top-emitting transparent cathodes of the plurality of auxiliary top-emitting devices are formed in the second light-emitting region on one sides of the top-emitting light-emitting layers away from the top-emitting reflective anodes through the one-time patterning process, the fabrication method further includes the following step.

Step S800, a second color film part including a plurality of second color filters are formed in the second light-emitting region on a side of the light-emitting member away from the first color film part.

In order to more clearly understand the fabrication method of the display substrate provided by embodiments of the present disclosure, detailed description is further made as follows.

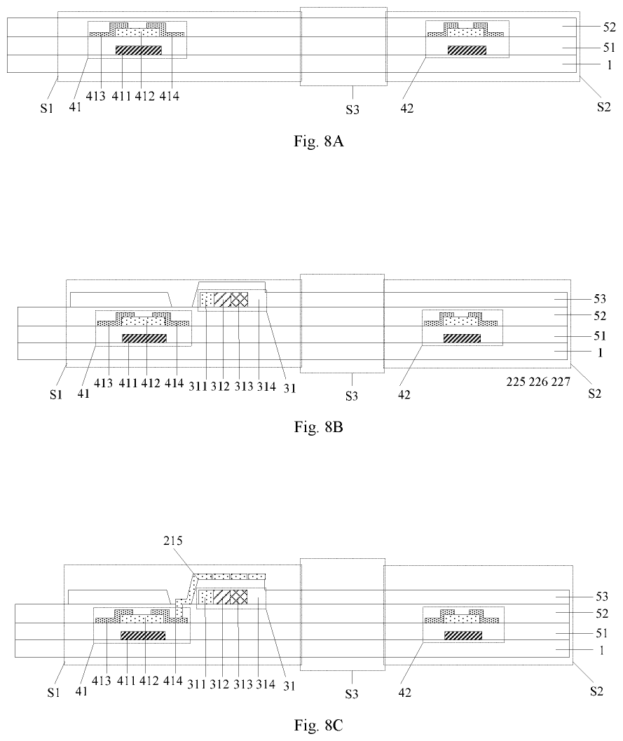

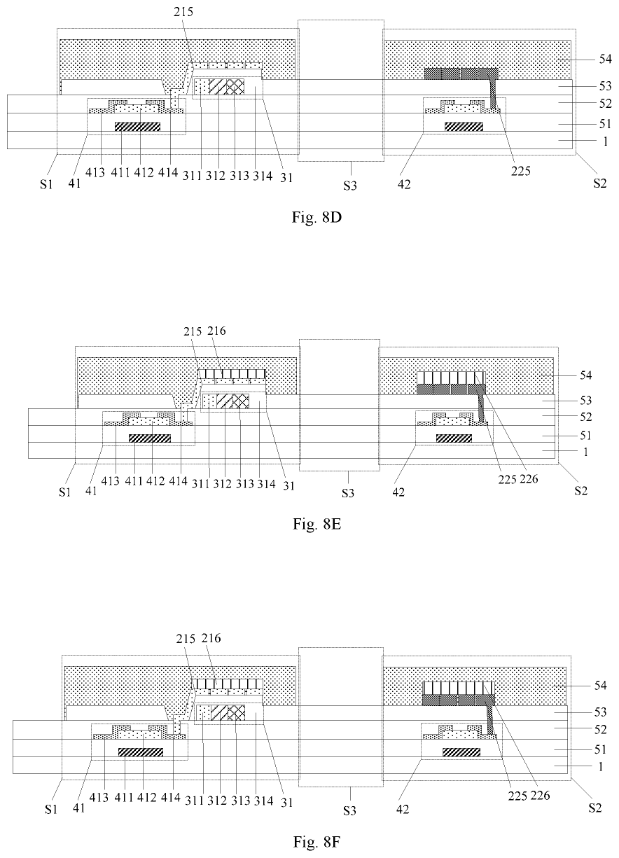

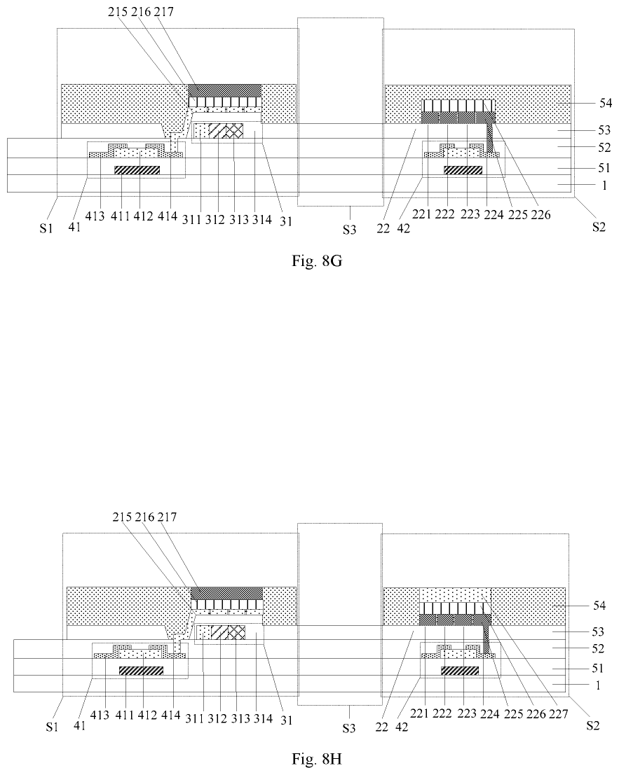

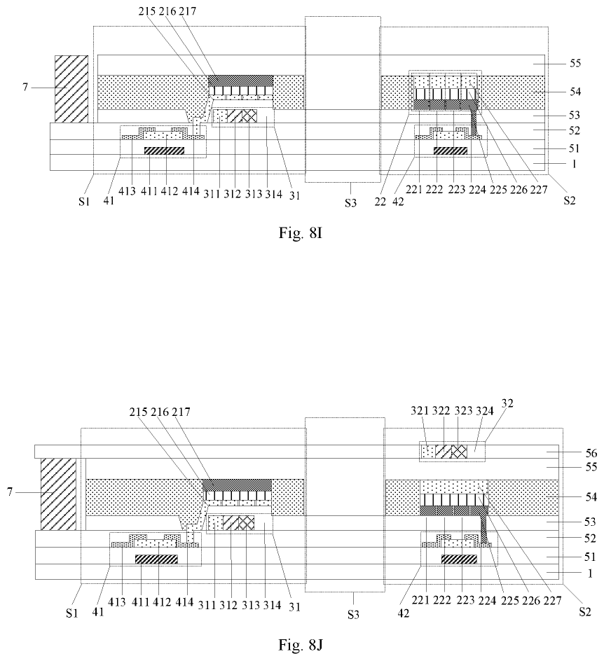

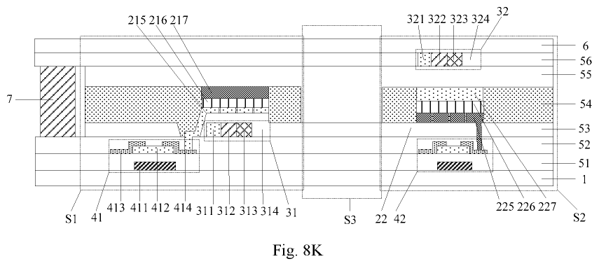

In a first step, all film layers of first thin-film transistors 41 and second thin-film transistors 42 are formed on the base substrate 1 through a patterning process, that is, a gate 411, a gate insulation layer 51, an active layer 412, a source electrode 413, a drain electrode 414 and a passivation layer 52 are formed on a side of the base substrate 1 in sequence, as shown in FIG. 8A.

In a second step, a pattern of the first color film part 31 of four R/G/B/W sub-pixels is formed on the above substrate, a pattern of a first flat layer 53 is formed, and the plurality of first color filters of the first color film part 31 may be: a first auxiliary color filter 311, a second auxiliary color filter 312, a third auxiliary color filter 313 and a fourth auxiliary color filter 314, as shown in FIG. 8B.

In a third step, patterns of the bottom-emitting transparent anodes 215 of a bottom-emitting region (namely, the first light-emitting region S1) are formed on the above substrate, as shown in FIG. 8C.

In a fourth step, patterns of the top-emitting reflective anodes 225 of a top-emitting region (namely, the second light-emitting region S2) are formed on the above substrate, as shown in FIG. 8D.

In a fifth step, a pattern of a pixel defining layer 54 is formed on the above substrate, as shown in FIG. 8E.

In a sixth step, patterns of the bottom-emitting light-emitting layers 216 and the top-emitting light-emitting layers 226 are formed on the above substrate, as shown in FIG. 8F.

In a seventh step, patterns of the bottom-emitting reflective cathodes 217 are formed in the bottom-emitting region (namely, the first light-emitting region S1) of the above substrate, as shown in FIG. 8G.

In an eighth step, the top-emitting transparent cathodes 227 are formed in the top-emitting region (namely, the second light-emitting region S2) of the above substrate, as shown in FIG. 8H.

In a ninth step, a thin-film encapsulation layer 55 is deposited by a chemical vapor deposition (CVD) method, and a material of the thin-film encapsulation layer 55 may be silicon nitride (SiN), so that surface encapsulation is performed on the above substrate, as shown in FIG. 8I.

In a tenth step, the second color film part 32 is formed in the second light-emitting region of the above substrate, a periphery of the above substrate is coated with Dam glue which serves as sealant 7, and a filler is formed on the above substrate to serve as a packing layer 56, as shown in FIG. 8J.

In a tenth step, the above substrate is encapsulated with an encapsulation cover plate 6, as shown in FIG. 8K.

In an embodiment of the present disclosure, the display substrate is provided with the bottom-emitting light-emitting unit 21 in the first light-emitting region S1 and the top-emitting light-emitting unit 22 in the second light-emitting region S2, and apart from the first light-emitting region S1 and the second light-emitting region S2, the display substrate is further provided with the transparent region S3, thus transparent display may be realized while double-side display may be realized, a display effect of a transparent product is improved, and an application range of the transparent product is widened.

Although embodiments of the present disclosure are described, those skilled in the art can make other changes and modifications to these embodiments once they known a basic inventive concept. Therefore, the appended claims intend to be explained as including embodiments and all changes and modifications falling within the scope of the present disclosure.

Apparently, those skilled in the art can make various modifications and variations to embodiments of the present disclosure without departing from the spirit and the scope of embodiments of the present disclosure. In this case, if these modifications and variations of embodiments of the present disclosure fall within the scope of the claims of the present disclosure and their equivalents, the present disclosure also intends to contain these modifications and variations.

1. A display substrate, comprising:
a base substrate, having a first light-emitting region, a second light-emitting region and a transparent region, wherein an orthographic projection of the transparent region on the base substrate does not overlap an orthographic projection of the first light-emitting region on the base substrate and an orthographic projection of the second light-emitting region on the base substrate; and
a light-emitting member, located on a side of the base substrate and comprising a bottom-emitting light-emitting unit located in the first light-emitting region and a top-emitting light-emitting unit located in the second light-emitting region.

2. The display substrate according to claim 1, wherein the bottom-emitting light-emitting unit comprises a plurality of auxiliary bottom light-emitting devices emitting white light; and
the display substrate further comprises: a first color film part located between the base substrate and the light-emitting member and in the first light-emitting region, and the first color film part comprises a plurality of first color filters which are in one-to-one correspondence with the auxiliary bottom light-emitting devices.

3. The display substrate according to claim 2, wherein each auxiliary bottom light-emitting device comprises: a bottom-emitting transparent anode, a bottom-emitting light-emitting layer and a bottom-emitting reflective cathode which are located on a side of the first color film part away from the base substrate in sequence; and
in a same bottom-emitting light-emitting unit, bottom-emitting transparent anodes of all auxiliary bottom light-emitting devices are mutually spaced, bottom-emitting light-emitting layers of all auxiliary bottom light-emitting devices are of an integrated structure, and bottom-emitting reflective cathodes of all auxiliary bottom light-emitting devices are of an integrated structure.

4. The display substrate according to claim 2, wherein the display substrate further comprises a first driving unit located between the first color film part and the light-emitting member; and
the first driving unit comprises: a plurality of first thin-film transistors which are electrically connected with the auxiliary bottom light-emitting devices in one-to-one correspondence.

5. The display substrate according to claim 4, wherein an orthographic projection of the first driving unit on the base substrate does not coincide with an orthographic projection of the bottom-emitting light-emitting unit on the base substrate.

6. The display substrate according to claim 3, wherein the top-emitting light-emitting unit comprises a plurality of auxiliary top-emitting devices emitting white light; and
the display substrate further comprises: a second color film part located on a side of the light-emitting member facing away from the base substrate and in the second light-emitting region, and the second color film part comprises a plurality of second color filters.

7. The display substrate according to claim 6, wherein each auxiliary top-emitting device comprises a top-emitting reflective anode, a top-emitting light-emitting layer and a top-emitting transparent cathode which are located on a side of the base substrate facing the second color film part in sequence; and
in a same top-emitting light-emitting unit, top-emitting reflective anodes of all auxiliary top-emitting devices are mutually spaced, top-emitting light-emitting layers of all auxiliary top-emitting devices are of an integrated structure, and top-emitting transparent cathodes of all auxiliary top-emitting devices are of an integrated structure.

8. The display substrate according to claim 6, wherein the display substrate further comprises a second driving unit located between the base substrate and the light-emitting member; and
the second driving unit comprises: a plurality of second thin-film transistors which are electrically connected with the auxiliary top-emitting devices in one-to-one correspondence.

9. The display substrate according to claim 8, wherein an orthographic projection of the top-emitting light-emitting unit on the base substrate covers an orthographic projection of the second driving unit on the base substrate.

10. The display substrate according to claim 7, wherein the bottom-emitting transparent anodes and the top-emitting transparent cathodes are on a same layer and made of a same material.

11. The display substrate according to claim 7, wherein the bottom-emitting reflective cathodes and the top-emitting reflective anodes are on a same layer and made of a same material.

12. The display substrate according to claim 1, wherein the orthographic projection of the transparent region on the base substrate is located between the orthographic projection of the first light-emitting region on the base substrate and the orthographic projection of the second light-emitting region on the base substrate.

13. The display substrate according to claim 12, wherein an area of the orthographic projection of the transparent region on the base substrate is approximately equal to an area of the orthographic projection of the first light-emitting region on the base substrate.

14. A display device, comprising a display substrate, the display substrate comprising:
a base substrate, having a first light-emitting region, a second light-emitting region and a transparent region, wherein an orthographic projection of the transparent region on the base substrate does not overlap an orthographic projection of the first light-emitting region on the base substrate and an orthographic projection of the second light-emitting region on the base substrate; and
a light-emitting member, located on a side of the base substrate and comprising a bottom-emitting light-emitting unit located in the first light-emitting region and a top-emitting light-emitting unit located in the second light-emitting region.

15. A fabrication method of the display substrate according to claim 1, comprising:
providing a base substrate, wherein the base substrate has a first light-emitting region, a second light-emitting region and a transparent region;
forming a plurality of bottom-emitting transparent anodes of a plurality of auxiliary bottom light-emitting devices in the first light-emitting region on a side of the base substrate through a one-time patterning process;
forming a plurality of top-emitting reflective anodes of a plurality of auxiliary top-emitting devices in the second light-emitting region on a side of the base substrate through a one-time patterning process;
forming a plurality of bottom-emitting light-emitting layers of the plurality of auxiliary bottom light-emitting devices and a plurality of top-emitting light-emitting layers of the plurality of auxiliary top-emitting devices on one sides of the bottom-emitting transparent anodes away from the base substrate through a one-time patterning process;
forming a plurality of bottom-emitting reflective cathodes of the plurality of auxiliary bottom light-emitting devices in the first light-emitting region on one sides of the bottom-emitting light-emitting layers away from the bottom-emitting transparent anodes through a one-time patterning process; and
forming a plurality of top-emitting transparent cathodes of the plurality of auxiliary top-emitting devices in the second light-emitting region on one sides of the top-emitting light-emitting layers away from the top-emitting reflective anodes through a one-time patterning process.
